(19) United States
(12) Patent Application Publication
(10) Pub. No.: US 2024/0297512 A1
(43) Pub. Date: Sep. 5, 2024

(54) Battery management system

(71) Applicant: LIMATECH, TOULOUSE (FR)

(72) Inventors: Luc POUYADOU, BRIGNOUD (FR); Maxime DI MEGLIO, SAINT ORENS (FR); Florence ROBIN, SAINT ORENS (FR)

(21) Appl. No.: 17/928,705

(22) PCT Filed: Jul. 23, 2021
(86) PCT No.: PCT/EP2021/070674

§ 371 Date: May 2, 2023

(30) Foreign Application Priority Data
Jul. 27, 2020 (FR) FR2007923

(51) Int. Cl. H02J 7/00

(52) U.S. Cl. CPC H02J 7/0031; H02J 7/0013; H02J 7/005; H02J 7/007182

(57) ABSTRACT

The invention relates to a battery management system (BMS) for accumulators, the batteries being capable of being constituted by a single element or several single elements which can be arranged in a modular assembly and connected in series or in parallel, and by an electromagnetic or electronic disconnection device connected, on the one hand, to at least one pole of a cell and, on the other hand, to a terminal of the same polarity of a modular assembly or a battery, the BMS comprising at least one single device for detecting deep discharges, overcurrent discharges and short-circuit discharges by measuring the voltage at the battery terminals.

### TECHNICAL FIELD OF THE INVENTION

The present invention relates to the field of lithium batteries for accumulators, and in particular the securing of said batteries.

### STATE OF THE PRIOR ART

Accumulator batteries are made up of electrochemical elements that can be connected in series or in parallel to obtain the necessary voltage and current.

Existing batteries, for example and non-limitingly those intended for the aviation field, using lead or nickel-cadmium, have a high mass, a short life and a high self-discharge and require regular maintenance. However, due to their low energy density, they pose little risk of overheating and fire. Often, a fuse or circuit breaker is sufficient to provide short circuit protection.

In the event of a short circuit or overcurrent, it is necessary to disconnect the battery to avoid damaging it and to avoid excessive heating of the battery or its connection cables.

Lithium batteries also require overcurrent and short circuit protection circuits. Generally, electromechanical circuit breakers or fuses are used, or electronic circuits that measure the current and control a switching device. However, measuring a current is not simple.

There are several current measurement methods (shunt, magnetic measurement or by thermal effect). However, these may involve high consumption, which may require the use of a “standby” mode and an “active” mode. Moreover, this is hardly compatible with protection against short circuits, which can occur at any time.

In addition, a heat engine starter battery must supply a very high current for a few seconds to a few tens of seconds. Thus, the current of the circuit breaker (switching device) must be set to a fairly high value, of the order of half the short-circuit current (the maximum power supplied by a battery is reached when the voltage is half of the open-circuit voltage, and the current is half of the short-circuit current). With aging, or at low temperatures, the internal resistance of battery cells increases, so the short-circuit current decreases. It is possible that this current becomes lower than the tripping current. In this case, the protection is no longer assured. Use under these conditions may lead to a complete discharge of the battery in its internal resistor, causing strong overheating, then a fire.

Finally, for example and without limitation, a 17 Ah non-modular battery can supply a short-circuit current of more than 2000 A. Thus, the cut-off device ensuring the disconnection of the battery from its utilization circuit must be able to withstand this current. Semiconductors that can withstand this current are not common and in practice, several lower-current components are connected in parallel. The balance of the currents is very difficult to achieve, which requires oversizing the components. Measuring a 2000 A current also poses problems of compromise between precision and static consumption.

### DISCLOSURE OF THE INVENTION

The present invention aims to overcome certain drawbacks of the prior art by proposing a method for detecting abnormal conditions and a lithium battery management system that is simple, reliable, and easily adaptable to different intensities and voltages for single or modular elements.

An object of the invention is to enable the method to detect the deep discharge, short-circuit discharge and overcurrent discharge conditions of lithium batteries without going through a current measurement.

This object is achieved by a method for detecting abnormal operating conditions (deep discharges, overcurrent discharges and short-circuit discharges) of a single battery element or of a plurality of single elements comprising the following steps:
Sampling, at the common point of at least two resistors of a divider bridge with at least two resistors, at least one voltage proportional to the voltage at the terminals of the single element or of the set of single elements;
comparing the detected voltage with a reference threshold;
said comparison with said reference threshold triggers the implementation of:
an evaluation of the evolution to come by an integral, evaluated analogically or digitally;
a comparison of this evaluation with a detection voltage threshold Td from which a disconnection of the single element or of the set of monitored single elements is carried out with respect, at least, to the terminals of the battery.

According to another feature, the step of evaluation by digital integral comprises:

steps for calculating the evolution slope (P) of the voltage curve by using at least two measurements taken
at least one step of comparing the calculated slope with a stored “RapidThreshold” value, i.e., if the slope exceeds the “RapidThreshold” value, applying a weight coefficient increasing the acceleration of the evolution of the integral so that it crosses the trigger voltage threshold Td more quickly, or if it is not exceeded, a weight coefficient without acceleration effect.

Another aim is to enable the management system to monitor the deep discharge, short-circuit discharge and overcurrent discharge conditions of lithium batteries without going through a current measurement.

This object is achieved by a battery management system (BMS) for accumulators, said batteries being capable of being constituted by a single element or several single elements that can be arranged in a modular assembly and connected in series, in parallel or in a plurality of series modular assemblies associated in parallel to form a battery; said system comprises means suitable for performing the steps of a detection method according to the invention.

According to another feature, the battery management system (BMS) comprises at least:

a voltage divider bridge with at least two resistors, for sampling at least one voltage proportional to the voltage at the terminals of the single element or of the set of single elements of the battery,
a detection device for detecting abnormal conditions,
a disconnection device,
said detection device communicating with the disconnection device to activate it in the event of detection of abnormal conditions, said disconnection device being connectable to the battery and comprising at least two MOSFETs.

Another object is to propose a digital solution for a detection device.

This object is achieved by the battery management system (BMS) for accumulators according to the invention, comprising a microprocessor equipped with at least one storage memory allowing the storage of at least one “Refintegration” threshold variable and a stored detection voltage value Td, the memory also containing the program executed by the microprocessor allowing the collection of the voltage curve points, the comparisons and decisions, the implementation of the equations allowing the integration, the microprocessor receiving as input the voltage V_{global} coming from the common point of the divider bridge between a resistor R1 and a resistor R2 and storing the measurements according to a determined frequency to observe the voltage curve V_{global}, and comparing the values of the voltage curve V_{global} with the “Refintegration” value, then when crossing of the “Refintegration” threshold is detected, said threshold being defined by the value stored in the memory, triggering the integration calculations of the curve V_{global} and comparing the values of the calculated integration curve (V_{integ}) with a stored detection voltage value Td to activate the disconnection device effecting the cut-off.

According to another feature, the storage memory of the microprocessor also comprises the value of a “RapidThreshold” variable stored in order to determine, by comparing the variation dV of the voltage V_{global} between two successive instants t1 and t2 with the “RapidThreshold,” whether the calculation of the integral of the voltage curve V_{global} must take a weight coefficient into account or not.

According to another feature, the calculation of the integral comprises taking into account the “Slope and/or Ordinate” variables calculated by the microprocessor from the data of the recorded voltage curve V_{global}.

Another object is to propose an analog solution for a detection device.

This aim is achieved by the battery management system (BMS) for accumulators according to the invention, comprising at least around one comparator U1, a divider bridge (R1, R2, or R9, R4) mounted between the terminals of the modular assembly of the battery or of a single element of the battery whose common point with the resistors is connected to the input of the negative terminal of the comparator U1 to supply a voltage whose value is proportional to the voltage value V1 at the terminals of the battery, in the ratio defined by the values of the two resistors (R1, R2 or R9, R4), and the positive terminal of the comparator is connected to a diode or a supply cell to define the reference voltage V2.

Thus, by changing the resistor and reference voltage values, the system will be able to adapt to batteries comprising different voltage and current characteristics.

According to another feature, the integrator assembly comprises

a resistor R5 connected between the common point of the divider bridge R1, R2 and the negative input of the comparator U1, and a resistor R8, capacitor C1 set mounted in series by a common terminal, connected by the other terminal of C1 to the output of the comparator U1, the other terminal of R8 being connected to the common point of the two resistors R5, R8 and to the negative input of U1, the values R5 and C1 being adjusted to set the intervention time of the disconnection before the deterioration of the battery in the event of overcurrent detection.

According to another feature, a diode D2 is connected in parallel to resistor R5, with its cathode connected to the common point of the divider bridge to change the integration time constant of the integrator circuit in the event of an overcurrent or a short circuit.

According to another feature, the comparator U1 has, at its output terminal, a voltage whose value characterizes a “non-conductive” state if the voltage applied to the input of the negative terminal of the amplifier U1 is greater than the value of the reference voltage V2 and a “conductive” state if the value of the voltage applied to the input of the negative terminal of the amplifier U1 is lower than the value of the reference voltage V2.

According to another feature, the detection device comprises a capacitor C3 mounted in parallel with R2 that, combined with R1, forms a filter to filter out high-frequency disturbances.

According to another feature, mounted in parallel with R9 are

a series assembly consisting of a resistor R3, a diode D3 with the cathode oriented toward the positive terminal and a Zener diode D4 with the cathode oriented toward the common point of the divider bridge R9, R4,
a capacitor C5 connecting the common point of the bridge R9, R4 to the negative terminal of the battery or of the cell or of the modular assembly of single elements.

According to another feature, a comparator circuit U2 with hysteresis, disposed downstream of the comparator circuit U1, comprises a hysteresis assembly around the amplifier U2 that receives, at the input of its negative terminal, the value of the voltage of the output of the amplifier U1.

According to another feature, the hysteresis comparator U2 comprises resistors R3, R4 mounted as a divider bridge between the positive and negative terminals of the battery and whose point common to R3 and R4 is connected to the positive input of the comparator U2 and a resistor R6 of which connects the output of U2 to its positive input to define the threshold and the hysteresis of the hysteresis comparator circuit comprising the amplifier U2.

According to another feature, the detection device comprises a resistor R7 connected to the positive terminal of the battery, in series with a diode D1, in the forward direction in normal operation, and a capacitor C2 connected on the one hand to the cathode of the diode and on the other hand to the negative terminal of the battery to allow it to be charged during normal operation; the supply inputs of the two comparators U1, U2 are connected to the point common to D1 and C2, this common point being used to maintain the supply of the amplifiers U1 and/or U2 when the battery voltage collapses following a short circuit to allow the activation of the disconnection.

According to another feature, the reference voltage V2 at the positive input of the comparator U1 is provided by a Zener diode D2, said Zener diode D2 being connected by a resistor R1 to the point common to D1 and C2, the cathode of the Zener diode D2 also being connected by a capacitor C1 to the negative terminal of the battery or modular set of elements.

According to another feature, the hysteresis comparator U2 comprises a capacitor connected in parallel with a resistor R4 and which, combined with another resistor R3 or R2, forms a filter to filter out high-frequency disturbances and set a minimum tripping time.

According to another feature, the positive input of the hysteresis comparator U2 is connected by a resistor R2 to the point common to R3, R9 and R7.

According to another feature, the detection device comprises a flip-flop connected to the output of U1 or U2 to store each action of the detection device after each detection of deep discharges, overcurrent discharges and short-circuit discharges.

Another object is to propose a disconnection device, usable with the detection device, formed from electronic components associated in an assembly protecting the components of the disconnection device.

This other object is achieved by the disconnection device comprising a switching device (30) in which

a first MOSFET M1 is connected by its source to the negative terminal of a set of single elements, said MOSFET M1 receiving, on its gate, the voltage source that drives M1, said source delivering a voltage chosen so that M1 is on,
a Zener diode D3, connected in opposition between the gate and the source of M1, and a capacitor C2 protect the gate of the MOSFET from excessively high or high-frequency voltages, and
a Zener diode D1 mounted in opposition between the gate of M1 and the drain and with a resistor R3 and a diode D2 in the forward direction in the drain-to-grid direction limit the switching speed of M1, and
a circuit consisting of a Schottky diode D4 mounted in opposition on the drain of M1 and in series with a capacitor C1 and a resistor R1 connected to the positive terminal of the battery (4) to limit the overvoltage when opening M1, in parallel on the Schottky diode D4 a fixed resistor I1 is mounted connected on the one hand to the cathode of the diode and on the other hand to the drain of a second MOSFET M2 whose source is connected to the anode of the Schottky diode D4, the gate of M2 being controlled by an output of the detection circuit to prevent the load.

According to another feature, the disconnection device comprises a second switching device in which

a first MOSFET M1 connected by its source to the negative terminal of a set of single elements, the gate of this MOSFET M1 is controlled by a voltage, this source delivering a voltage chosen so that M1 is always on,
a circuit consisting of a Schottky diode D4 mounted in opposition on the drain of M1, in parallel on the diode D4 a fixed resistor I1 is mounted connected on the one hand to the cathode of the Schottky diode D4 and on the other hand to the drain of a second MOSFET M2 whose source is connected to the anode of the Schottky diode D4, the gate of M2 being connected to the positive terminal of said set of single elements,
a Zener diode D6 and a resistor R6 in series with the gate of M2, the Zener diode D6 being mounted in the forward direction in the drain-gate direction,
a Zener diode D5 mounted in opposition between the gate and the source of M2 to define, with the Zener diode D6, the value of the voltage at the gate of M2 and at which M2 is on,
a capacitor C5 connected between the gate and the source of M2 and in parallel with the Zener diode D5 to protect the gate of M2 from high-frequency voltages,
an optocoupler OP1 mounted between the gate and the source of M2 and in parallel with the capacitor C5 to block M2 in the event of the voltage or temperature of an element of the set of single elements being exceeded, the MOSFET M2 then cutting off the charge current.

Other features and advantages of the present invention are detailed in the following description.

### BRIEF DESCRIPTION OF THE FIGURES

Other features and advantages of the present invention will appear more clearly on reading the description below, done with reference to the appended drawings, in which:

FIG. 1 shows a diagram of the circuit of the discharge detection device (2) for detecting deep discharges, overcurrent discharges and short-circuit discharges, according to one embodiment;

FIG. 2 shows a diagram of the circuit of said detection device according to a variant;

FIG. 3 shows a diagram of an example of a circuit for measuring current via a resistor known from the prior art and having the known drawbacks;

FIG. 4A shows the display of changes in the voltage at the terminals of the comparators U1 and U2 in the event of overcurrent according to one embodiment for a 24.4 Volt battery and a detection or trigger voltage Td of 16 Volts;

FIG. 4B shows the response of a digital integrator assembly operating according to the flowchart of [FIG. 4D] according to an embodiment used with a 16-volt battery and a detection or trigger voltage Td of 12 Volts;

FIG. 4C shows the response of an analog integrator assembly according to another embodiment used with a 16-volt battery and a detection or trigger voltage Td of 12 Volts;

FIG. 4D a flowchart explaining the program for calculating the response of a digital integrator assembly according to an embodiment with paralleling of analog embodiments;

FIG. 4E shows the response, in case of short circuit, of an analog integrator assembly according to an embodiment used with a battery of about 14 Volts and a detection or trigger voltage Td of 14 Volts in case of short circuit;

FIG. 4F shows the response, in case of short circuit, of a digital integrator assembly operating according to the flowchart of [FIG. 4D] according to an embodiment used with a battery of about 14 Volts and a detection or trigger voltage Td of 10 Volts;

FIG. 4G shows the response, in case of slow discharge, of an analog integrator assembly according to an embodiment used with a battery of about 14 Volts and a detection or trigger voltage Td of 14 Volts;

FIG. 4H shows the response, in case of slow discharge, of a digital integrator assembly operating according to the flowchart of [FIG. 4D] according to an embodiment used with a battery of about 14 Volts and a detection or trigger voltage Td of 10 Volts;

FIG. 4I shows the response, in case of discharge at V/2, of an analog integrator assembly according to an embodiment used with a battery of about 14 Volts and a detection or trigger voltage Td of 14 Volts to determine the maximum current of the battery;

FIG. 4J shows the response, in case of discharge at V/2, of a digital integrator assembly operating according to the flowchart of [FIG. 4D] according to an embodiment used with a battery of about 14 Volts and a detection or trigger voltage Td of 10 Volts to determine the maximum current of the battery;

FIG. 5 shows a diagram of the circuit of the first switching device on discharge of the disconnection device, according to one embodiment;

FIG. 6 shows a diagram of the circuit of the second switching device on charging of the disconnection device, according to one embodiment;

FIG. 7 shows a diagram of the interconnection between the battery management system (BMS) and the disconnection device, according to one embodiment;

FIG. 8 shows the diagram of a battery comprising a BMS and a disconnection device, according to one embodiment,

FIG. 9 shows the diagram a disconnection characteristic, obtained by the detection device as described and very close to that of a magnetothermal circuit breaker of the state of the art, according to one embodiment.

### DESCRIPTION OF EMBODIMENTS

The present invention relates to a method and a system (1) for managing batteries (BMS) for accumulators.

Said batteries may consist of a single element or of several single elements or cells that can be arranged in a modular assembly connected in series, in parallel or in a plurality of series modular assemblies associated in parallel to constitute a battery (4), and an electronic disconnection device (3) connected on the one hand to at least one pole of a cell and on the other hand to a terminal of the same polarity of a modular assembly or of a battery (4).

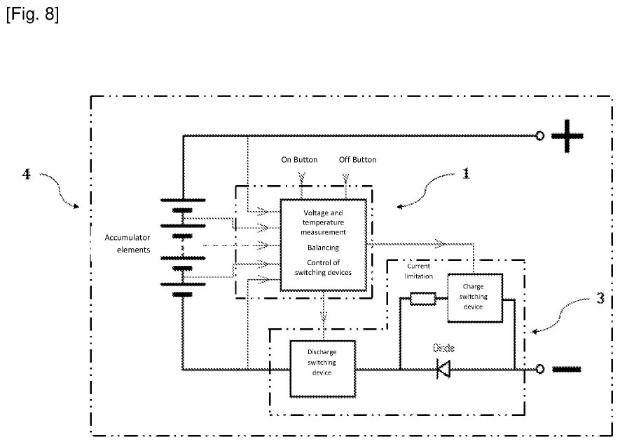

According to another variant, the battery management system (BMS) (1) for accumulators comprises at least one deep (or slow) discharge, overcurrent discharge and short-circuit discharge detection device (2) in each single element or modular assembly of the battery (4), which comprises at least one BMS device ([FIG. 8] illustrates a battery with a BMS device), said system (BMS) being characterized in that the detection device (2) is unique.

The detection device (2) comprises an analog or digital (Un) comparator U1 that directly compares a voltage that is proportional, in a determined ratio, to the voltage of the single element or of the modular assembly, without using a resistive shunt, with a reference voltage (V₂ or Refintegration) and evaluates the voltage variations to activate or not activate the disconnection of each single element or modular assembly of the battery (4) according to a detection voltage Td from which the disconnection device is actuated.

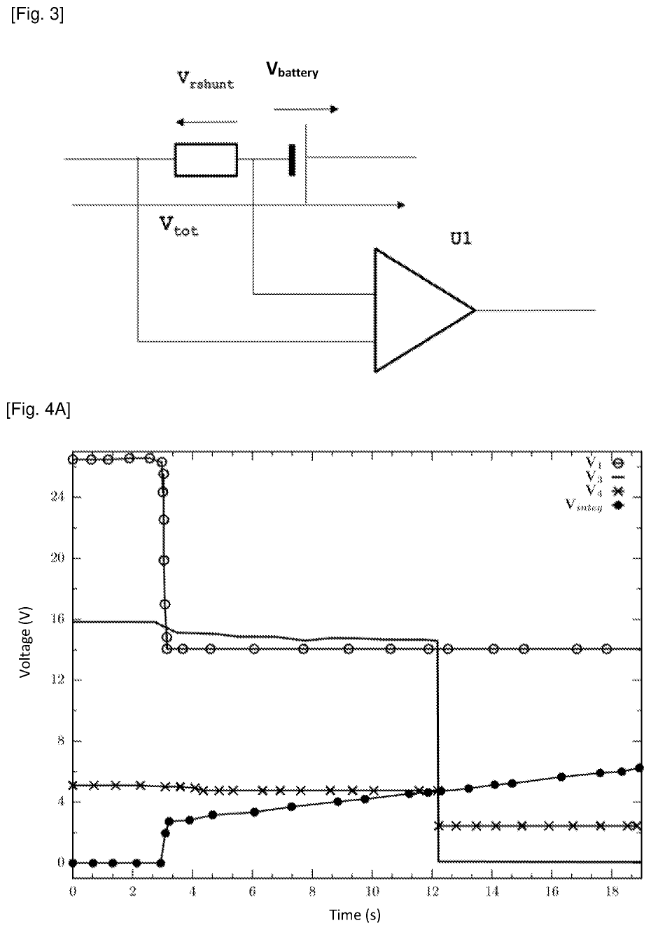

The proportion ratio between the measured voltage and the reference voltage corresponds to the ratio between the reference voltage (V₂ or Refintegration) and the detection or tripping voltage Td from which the disconnection device is actuated.

[FIG. 3] illustrates an example of current measurement by shunt resistor. This measurement involves putting a shunt in series on the line. The overall voltage Vₜₒₜ is given by Vₜₒₜ=V_{battery}−Vᵣₛₕᵤₙₜ with Vᵣₛₕᵤₙₜ=R*I the value across the terminals of the shunt resistor. Thus, the greater I is, the greater the voltage drop. In this case, the consumption of a comparator U1 is very high, 1 mA for a differential amplifier versus less than 10 pA for the voltage measurement.

Furthermore, the voltage V_{battery} measured across the terminals of the battery or of each element is of the form V_{battery}=ER*I, with E the open-circuit voltage, R the internal resistance and I the current delivered by the battery. E and R are known for a given battery and the voltage V_{battery} provides access to I, the delivered current. The maximum power that a battery is capable of supplying is close to the value (E/2)*(I_{cc}/2) (with E the open-circuit voltage and I_{cc} the short-circuit current). As the internal resistance tends to increase with aging of the battery, the maximum power then decreases with the aging of the battery. Disconnecting by monitoring the voltage V_{battery} rather than the current provides optimal protection for a battery throughout its life. It is then obvious that detection by measuring the voltage is advantageous.

In addition, in the event of a failure of one or two lines comprising a set of single elements or cells of the battery, the detection device of the battery management system (BMS) (1), as described according to the invention, is configured (in particular via detection by voltage measurement) to self-adapt the threshold or trigger voltage Td for detecting abnormal conditions (deep discharge, short-circuit discharge, overcurrent discharge) of the battery. In other words, the detection device of the battery management system (1) makes it possible to protect the battery irrespective of its state of aging.

The single accumulator elements of a battery (4) to be protected may, for example and non-limitingly, have the following characteristics:

Open-circuit voltage=3.3 V
Internal resistance=0.012 Ohm (with connections)
Maximum current=70 A; 120 A 10 s
End-of-discharge voltage=2 V
End-of-charge voltage=3.6 V
Maximum voltage=4 V

A battery (4) can be modeled by a perfect voltage source in series with an internal resistance. In the case, given by way of example, of an “8S1P” assembly of 8 single elements in series, for example and non-limitingly, there is an open-load (or end-of-charge) voltage of 26.4 V and an internal resistance of 0.1 Ohm (with connections). Thus, the short-circuit current can reach 264 A, while the maximum specified current is 120 A for 10 s. Overcurrent protection is therefore necessary.

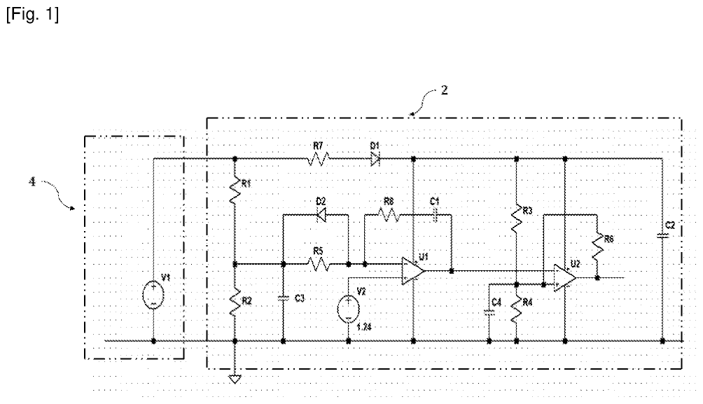

The diagram of the circuit for detecting faults (or abnormal conditions) claimed, illustrated by [FIG. 1], comprises a voltage divider R1 and R2, a voltage reference V2 of 1.24 V, for example and non-limitingly, and V1 is the voltage across the battery terminals that the device monitors. In the example above, the voltage at the end of discharge must not drop below 2 V per cell, i.e. 16 V for 8 cells in series. It is then possible to choose V1=16 V as the value of the detection or trigger voltage Td. For this value of the detection or trigger voltage, the division ratio of the voltage divider R1 and R2 will be chosen equal to V2/Td; i.e. 1.24 V/16 V=0.0775. Thus, in static operation, when the voltage of the battery (4) is greater than the detection or trigger voltage Td=16 V, the voltage applied to the—input of the amplifier U1 is greater than 1.24 V, its output is in the “non-conductive” state, the output of the comparator U2 is in the “conductive state” and operation is “normal” (no disconnection).

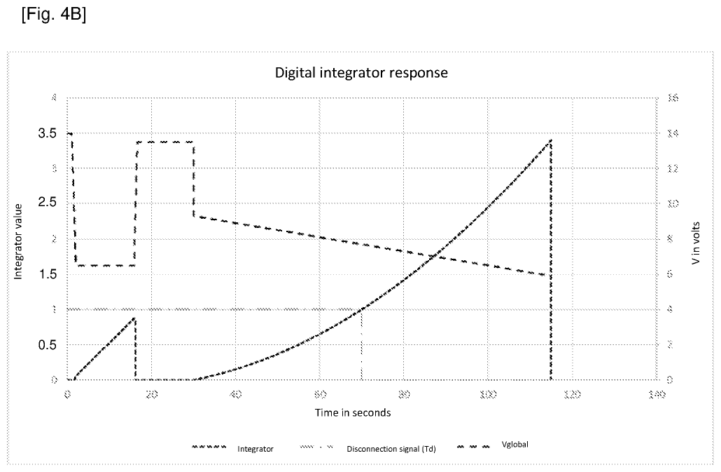

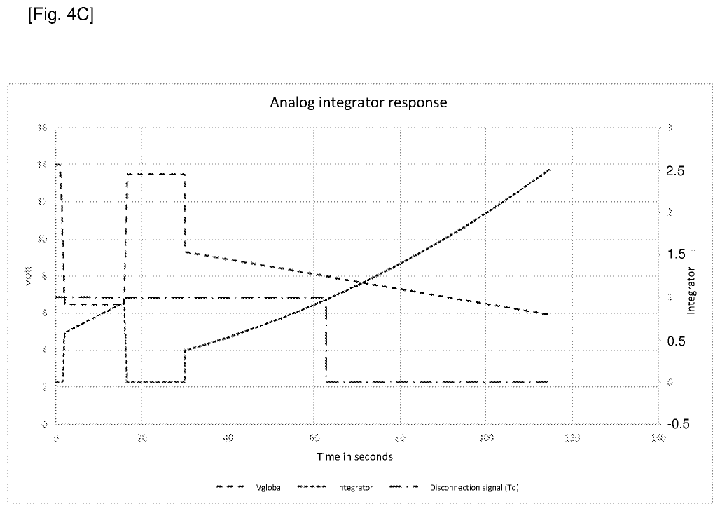

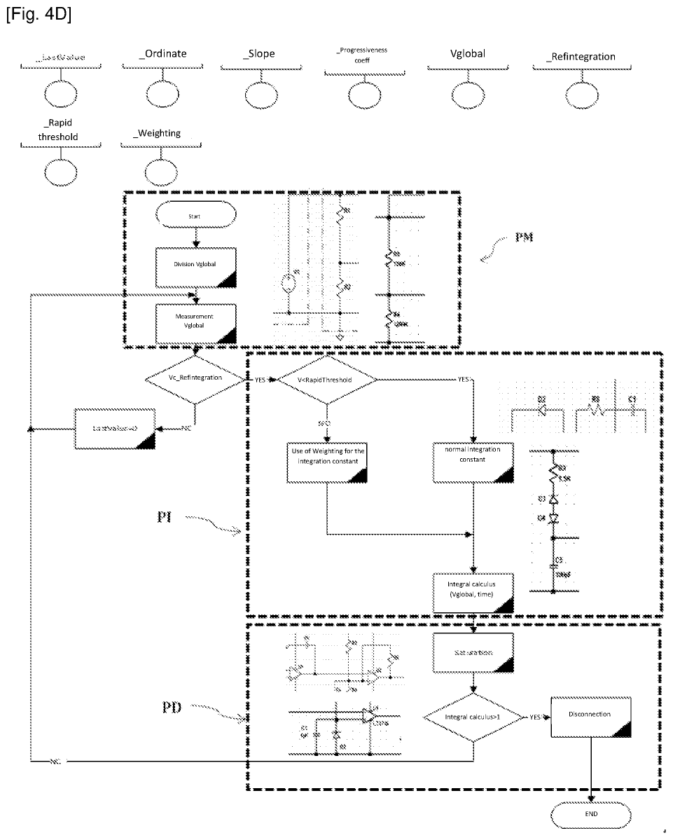

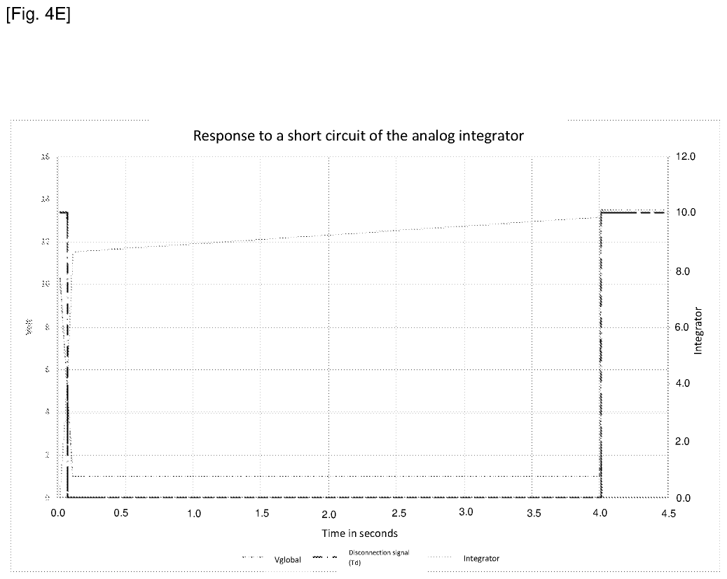

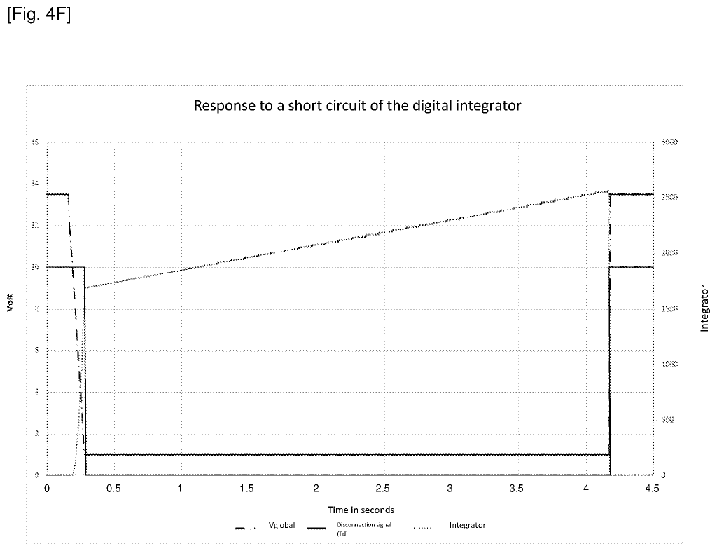

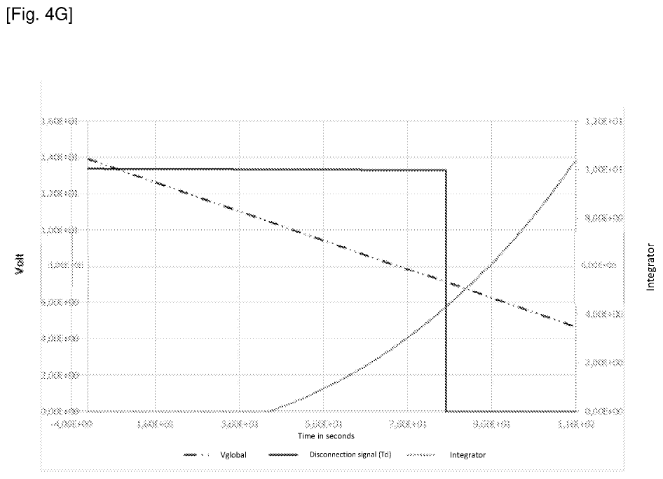

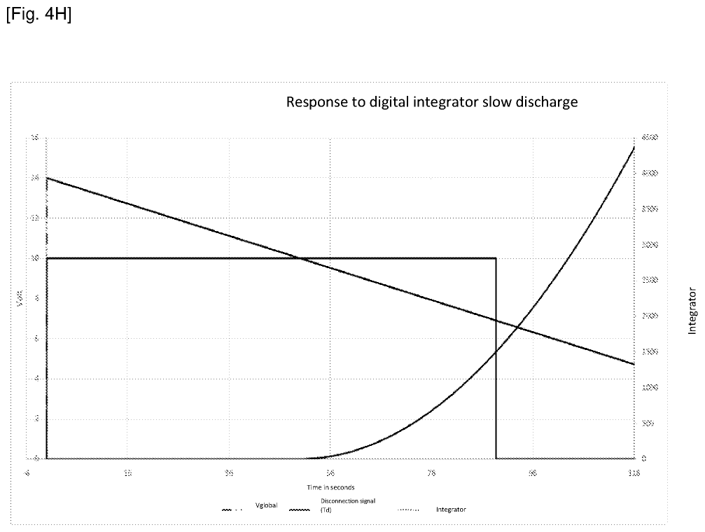

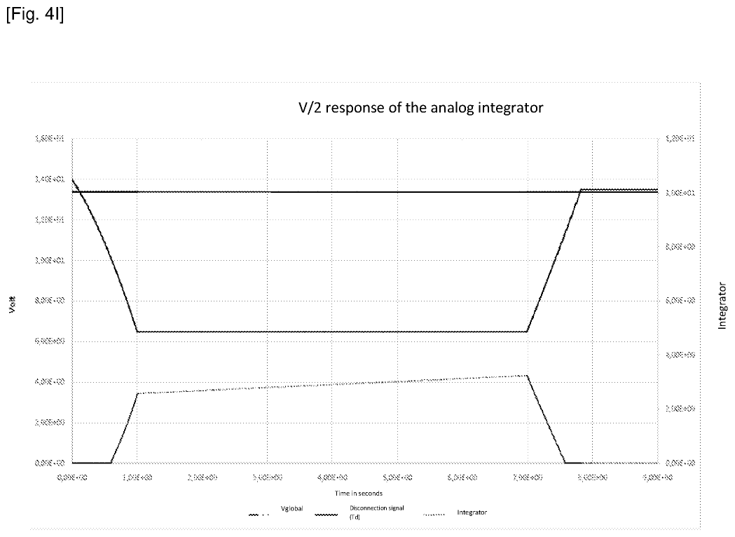

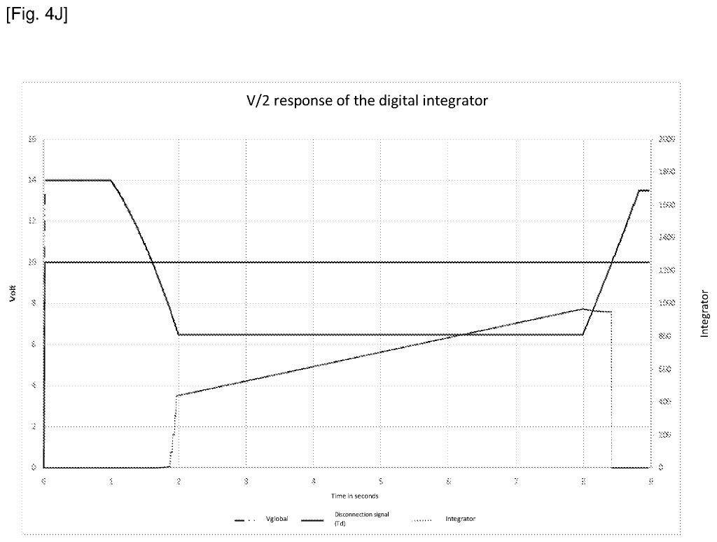

When the battery (4) slowly discharges (deep discharge) and its voltage drops below 16 V, the voltage applied to the—input of the amplifier U1 is less than 1.24 V, its output goes to the “conductive” state, the output of the comparator U2 switches to “non-conductive” and disconnection is activated. The output of the comparator (or amplifier) U1 is the integral of the voltage to be monitored according to an analog embodiment [FIG. 4C] or another digital embodiment [FIG. 4B]. Thus, as shown in these figures, if the voltage V_{global} changes linearly, the output of the integrator will be a second degree Function. If the voltage variation is a line of form ax+b, then the output is a function of type ax²+bx+c.

In the expression of the voltage across the terminals of a battery or of a single cell of the battery given by V_{battery}=ER*I, it is E, the open-circuit voltage, that decreases when the battery is completely discharged.

When the battery (4) provides a high current (overcurrent), for example 120 A, its voltage drops rapidly to 14.4 V (curve V1 [FIG. 4A]). The assembly above detects this situation.

In the event of a short circuit, the voltage V1 drops very quickly to a very low value and the voltage across the terminals of R2 is close to 0 V; this situation is also detected.

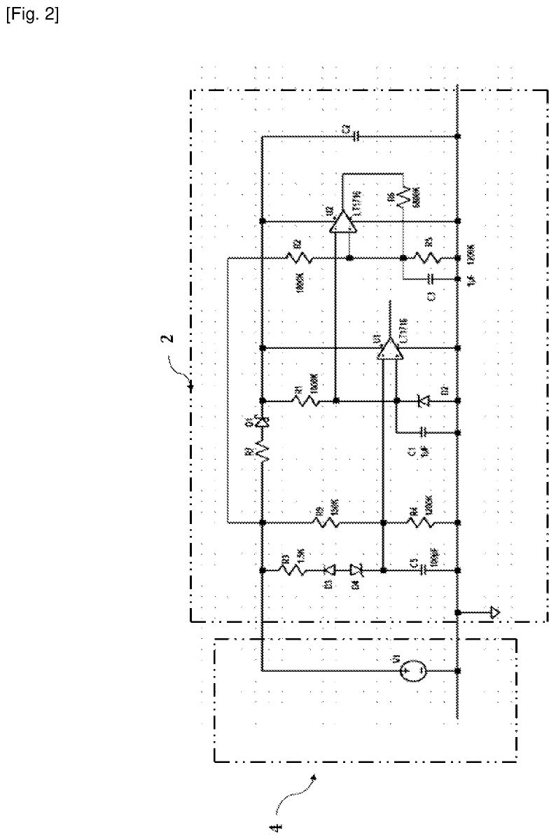

This same assembly could be used in another variant embodiment of [FIG. 2] (assembly with Zener diode D4) by replacing the resistors R1, R2 with the resistors R9, R4.

The detection device, as described in the present application, allows voltage variation detection with a non-linear progressiveness so that a strong overcurrent causes a disconnection of the battery after a period comprised between 10 ms and 100 ms and so that a low overcurrent causes a disconnection in a time comprised between 10 s and 100 s.

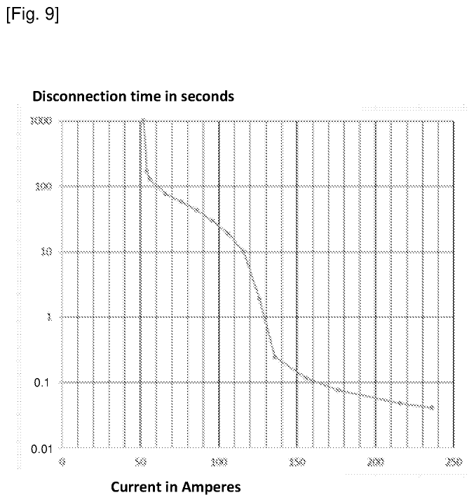

An overcurrent or a short circuit causes the battery components to overheat, which can lead to a fire. The dissipation of heat is proportional to the square of the intensity, thus the disconnection must be all the more rapid as the current overrun is important. A fuse or a magnetothermal circuit breaker cuts off the current in a time that is all the shorter as the current overrun is significant. This involves setting a maximum current and low battery protection in case of aging of the battery components, which cannot withstand a certain maximum value of the current due to the increase in the internal resistance of the battery with aging. In other words, in the event of aging, the fixed maximum current cannot be reached and the detection and protection of the battery will not be effective. On the contrary, in the present invention, which relates in particular to an overcurrent detection device based on a measurement of the evolution of the voltage across the terminals of the battery as a function of time, there is no constraint linked to setting a maximum current value. If the measured voltage is lower than a certain value corresponding to a low intensity of the current, then the disconnection time will be long, as illustrated in [FIG. 9]. If the voltage measured is lower than a certain value corresponding to a high current or a short circuit, then the disconnection time will be short (see [FIG. 9]). This makes it possible to secure the battery regardless of the aging of its components.

The functionality of detection by measuring the battery voltage combined with the use of an electronic circuit breaker makes it possible, in particular, to emulate the behavior of a thermomagnetic circuit breaker without the constraint of setting a maximum current to improve battery security. For example, [FIG. 9], which illustrates a disconnection curve obtained via an electronic circuit breaker according to the invention, is similar to that of a disconnection curve obtained via a shunt measurement and a thermomagnetic circuit breaker, but with much better accuracy.

The embodiments provide additional protection to the operation of the circuit to preserve the lifetime of the components or to avoid having to choose expensive components because they meet high specifications. These embodiments may not be fully combined with each other or with the main embodiment.

Thus, the detection device (2) comprises a voltage divider formed by at least two resistors R1 and R2, the voltage divider being connected to the terminals of the battery (4) to lower the voltage at the input of the comparator U1.

Similarly, a resistor R5 is connected between the common point of the divider bridge R1, R2 and the negative input of the comparator U1, and a resistor R8, capacitor C1 set mounted in series by a common terminal is connected by the other terminal of C1 to the output of the comparator U1 and the other terminal of R8 is connected to the common point of the two resistors R5, R8 and to the negative input of U1.

In another embodiment, a diode D2 is connected in parallel to resistor R5, with its cathode connected to the common point of the divider bridge. The diode D2 makes it possible, in this configuration, to change the integration time constant of the integrator assembly in the case of a very large or high current inrush, for example in the case of an overcurrent or a short circuit. This change in the integration time constant is equivalent to the use of weighting in the integration of the signal (voltage) in the case of a digital integrator (see below).

Thus, in the event of overcurrent, illustrated by [FIG. 4A], the battery (4) supplies a high current, for example 120 A, and its voltage drops rapidly to 14.4 V (V₁, [FIG. 4A]). The voltage difference between 26.4 V and 14.4 V is integrated by the integrator circuit R5-R8-C1 (in the mathematical integral sense) connected to the terminals of the amplifier U1, with an integration constant that mainly depends on R5-C1. Its output (V_{integr}, [FIG. 4A]) changes slowly from “0 V” to “Vcc short-circuit voltage” and the hysteresis comparator U2 switches (V₃, [FIG. 4A]) when its threshold (V₄, [FIG. 4A]) detection or trigger voltage Td is reached. Disconnection is activated. The time constant R5-C1 is set so that disconnection occurs before 10 s to 12 s in this case.

During a short circuit, the voltage V1 drops very quickly to a very low value and the voltage across the terminals of R2 is close to 0 V. Diode D2 conducts, the voltage at the-input of U1 is 0.6 V (the +input is still at 1.24 V) and the output of U1 changes quickly to “Vcc.” The output of the comparator U2 goes to “0” and the disconnection is activated.

In all these cases, a flip-flop stores this action, and it is necessary to “reset” (that is to say, reinitialize) the battery (4) by action on a “start” button accessible from outside the housing of the battery.

The capacitors C3 and/or C4 filter any high-frequency disturbances, and set the minimum tripping time.

The principle of measurement via an integrator circuit as described in the present application is a principle of measurement of an overall voltage that makes it possible to trace back to a current value. This principle is only valid in the battery field when the internal resistance of the voltage generator is known. In this case and only in this case, said integrator assembly can be used either analog (as shown in [FIG. 1]) or digital.

For example and non-limitingly, the response or output of a digital integrator can be calculated as follows:

Consider a voltage variation represented by x=(−0.25*V_{global}+2.5)*weighting, where V_{global} is a voltage obtained from the battery voltage by the use of a voltage divider bridge (R1-R2 or R9-R4) and weighting is a variable that allows the integration constant to be changed. The above equation can be modified according to the accumulators used.

The output or response of the digital integrator having the general form y=Integration(x), where Integration( ) represents the integral calculus, can be calculated using either as a first progressiveness equation consisting in taking the value of x, defined above, and raising it to an even power (2, 4, 6, 8, etc.), for example y=x².

To get even closer to the analog integrator ([FIG. 4A], [FIG. 4C]), a second progressiveness equation defined, for example and non-limitingly, by y=Rate*(−In(x)), with Rate an integration constant expressed in seconds, can be used. This equation makes it possible to imitate the behavior of a capacitor whose voltage across its terminals evolves like an exponential.

[FIG. 4D] shows a diagram for calculating the response of a digital integrator according to the second progressiveness equation. Each calculation step represents the components of the detection device that can be involved in the calculation operations. The diagram can be divided into three phases: a measurement (PM) and comparison phase, an integration phase (PI) and a disconnection phase (PD).

In the measurement phase (PM), the voltage divider bridge R1-R2 (or R9-R4) makes it possible to determine a measurement V=V_{global} of the voltage at the input of the detection device from the voltage V1 of the battery.

The “Refintegration” variable is the integration reference and corresponds to a voltage value below which the input signal V will be integrated. If the voltage V is greater than the “Refintegration” variable, the battery is in a situation of normal operation. If V is less than the “Refintegration” variable, the battery is operating abnormally and the process that can lead to the disconnection of said battery is triggered. This “Refintegration” variable is therefore equivalent to the reference voltage V₂. One then enters the integration phase, where the response of the integrator must be calculated.

If the voltage V is lower than the “Refintegration” variable, the program triggers either the use of a normal integration constant in the calculation performed, or the use of weighting for the integration constant. This weighting as represented in the PI box is used if the voltage is lower than a second comparison variable called “RapidThreshold,” which makes it possible to define a voltage threshold from which the “weighting” variable (defined above) is used in the calculation of the voltage variation or not. For example, and non-limitingly, the voltage variation has a general form of type x=(slope*V_{global}+ordinate)*weighting.

If the difference or variation of the input voltage V, dV, between a time t1 and a time t2 (or between two successive measurements of the voltage V), defined by dV=|V(t2)−V(t1)|, is greater than the “RapidThreshold” variable, the “weighting” variable takes the value 5, for example. If, on the contrary, said difference or variation of the input voltage V, dV, is less than the “RapidThreshold” variable, the “weighting” variable takes the value 1. Which corresponds to using a normal integration constant.

The voltage measurement time pitch can be comprised, for example and non-limitingly, between 1 ms to 100 ms. The value of the “RapidThreshold” variable can be defined according to the measurement time pitch and by monitoring the voltage variation between two times t1 and t2, corresponding to said time pitch, used to perform the voltage measurements, in order to improve the conditions for detecting abnormal conditions. For example, and non-limitingly, for [FIG. 4B], the measurement time pitch used is 10 ms and the “RapidThreshold” value is 0.01 Volt. This corresponds to a voltage drop dV=0.01 Volt every 10 ms.

The “Ordinate” and “Slope” variables obtained by storing the measurement points and calculating, for example by fitting the stored voltage data or by using two points of the stored voltage curve between two times t1 and t2 to deduce the “slope” (for a linear voltage variation) then the “ordinate,” make it possible to define the voltage variation. In the example where x=(−0.25*V_{global}+2.5)*weighting, the slope is −0.25 and the ordinate is 2.5.

The step of comparing the voltage variation dV is equivalent to a step of comparing the calculated slope with the stored “RapidThreshold” value, i.e., if the slope exceeds the “RapidThreshold” value, applying a weight coefficient (for example, 5) increasing the acceleration of the evolution of the integral so that it crosses the trigger voltage threshold Td more quickly, or if it is not exceeded, a weight coefficient without acceleration effect (for example, 1).

Once the voltage variation is obtained, the signal is integrated according to the second progressiveness equation, for example. The output signal thus corresponds to the integration of the input signal.

The “Progressiveness coeff” variable corresponds to an integration constant (Rate in the second progressiveness equation).

In the embodiment by digital integrator, those skilled in the art will understand that the assembly using the comparators U1 and U2 is replaced by a microprocessor playing the role of a digital comparator (Un). Said microprocessor is equipped with a storage memory allowing the storage of the “Refintegration” and “RapidThreshold” threshold variables and the “Ordinate” and “Slope” calculation variables defined according to these thresholds. The memory also contains the calculation program allowing the collection of the voltage curve points (V_{global}, etc.), the comparisons and decisions, the implementation of the equations, the integration and the decisions represented in the flowchart of [FIG. 4D]. As input, the digital circuit only receives the voltage V_{global} from the common point of a divider bridge between a resistor R1 and a resistor R2 and performs measurements according to a determined frequency to observe the voltage V_{global} curve, then from the detection of the crossing of the “Refintegration” threshold, which, in the example of [FIG. 4B], is chosen to be less than 3 volts per cell element or 12 volts for a battery of 4 cell elements in series from this reference voltage V₂, the microprocessor program triggers the calculations to obtain the comparison with the “RapidThreshold” variable of the variation dV of the voltage V_{global} between two successive instants t1 and t2 (or between two successive measurements) in order to determine the use or not of a “Weighting” variable. Thus, in the case of a start causing a significant drop in voltage from 14 to almost 6 Volts, the “RapidThreshold” variable is, for example and non-limitingly, set at 0.01 Volt in the example of [FIG. 4B]. The “RapidThreshold” variable will be crossed and the integration will be done with weighting to avoid an excessively fast cut-off preventing starting. In the diagram shown in [FIG. 4B], it is observed that the battery voltage having dropped rapidly to almost 6 Volts and remaining constant for about 18 seconds, the digital circuit integrates the constant value in a straight line, which remains below the detection or trigger voltage Td, which is chosen at 1 Volt. The response of the integrator or output voltage can, for example and non-limitingly, be obtained with a program such as the one defined in the appendix to this application where the “GeneralVoltage” variable corresponds to the voltage V_{global} at an instant t1=t, and the “LastGeneralVoltage” variable represents the value of the voltage V_{global} at instant t2=t-1. The “ORDINATE_ORIGIN” variable corresponds to the “Ordinate” variable defined above and the “lastIntegratedValue” variable corresponds to the integral calculation or the integrator's response.

The calculation of the integral or of the integrator's response can comprise taking into account the “Slope and/or Ordinate” variables calculated by the microprocessor from the data of the recorded voltage curve V_{global}.

Integration is triggered as soon as the overall voltage V_{global} drops below V₂=Refintegration=9 Volts.

Then, during its use, the voltage of the battery drops suddenly from 14 Volts to about 9 Volts, then decreases slowly over time along a straight line down to 6 Volts. The ordinate of the line is approximately 2.3 Volts and the slope is lower than previously, and the variation dV of the voltage between two successive measurements may be greater (depending on the value of the slope) than the “RapidThreshold” variable (for example, 0.01 Volt in the example shown in [FIG. 4B]).

When the value at the output of the integration reaches the threshold corresponding to the detection or trigger voltage Td of 1 volt, the cut-off is triggered.

Finally, in the digital version or variant, during a short circuit, the voltage V_{global} drops very quickly to a very low value, a short circuit detection threshold is stored, and as soon as the processor detects the crossing of this threshold, it activates the disconnection signal.

In [FIG. 4B] illustrating the response or output signal of a digital integrator according to the example described above, the digital integrator exhibits behavior similar to that of an analog integrator ([FIG. 4C]) in the time interval comprised between t=40 s and approximately t=120 s.

In the disconnection phase, the calculation of the response is used to check whether a disconnection should be triggered (or activated) or not. Disconnection is activated when the response of the integrator is greater than a given threshold corresponding to the detection or trigger voltage Td. In the example above, illustrated by [FIG. 4B], [FIG. 4C] and [FIG. 4D], this threshold is set at approximately 1 or 1.24 Volts. For example and non-limitingly, the threshold value can be normalized to 1.

[FIG. 4E] and [FIG. 4F] respectively illustrate the response of an analog integrator and a digital integrator when a short-circuit is detected. The measurement time step is set at 10 ms and the value of the “RapidThreshold” variable is equal to 0.1 V.

In the example of [FIG. 4F] showing the response of a digital integrator, a drop in the voltage V_{global} across the terminals of the battery can be observed from a value of approximately 14 V to a value close to 0 V in a time interval of between 0.2 s and 0.3 s and in which the digital integrator circuit integrates the input signal with a weighting value=150 to increase the acceleration of the evolution of the integral. This weighting is performed so that the output signal or the response crosses the triggering threshold Td=10 V as quickly as possible (which is set at 14 V in the case of the analog integrator). This value of Td can be normalized to 1, as mentioned above. From 0.3 s to about 4.2 s, the value of V_{global} remains constant and close to 0 V, and the response of the digital integrator circuit is a straight line that passes above the trigger voltage Td of the disconnection after a duration of about 1 s. When the battery returns to normal operation, after 4.2 s, the response of the digital integrator circuit is zero. The behavior of the digital integrator is similar to that of the analog integrator circuit illustrated by [FIG. 4E].

[FIG. 4G] and [FIG. 4H] respectively illustrate the response of an analog integrator and a digital integrator when a slow or deep discharge is detected. The measurement time step is also set at 10 ms and the value of the “RapidThreshold” variable is equal to 0.1 V.

As illustrated in [FIG. 4H], during the slow or deep discharge, the signal or the input voltage V_{global} changes as a descending straight line from 14 V to about 5 V in a time interval between 0 and 116 s. The digital integrator circuit (or digital integrator) integrates the input signal, taking into account a weighting value equal to 150. The disconnection process is triggered when the response curve is greater than the value of the trigger voltage Td, set in this example at approximately 10 V (which is set at approximately 14 V in the case of the analog integrator). Like in the cases of detecting abnormal conditions such as overcurrent ([FIG. 4B]), short circuit ([FIG. 4F]), the behavior of the digital integrator is also similar to that of the analog integrator circuit illustrated by [FIG. 4G] in case of slow discharge.

Thus, those skilled in the art will understand that the battery management system as described in the present application is suitable for detecting abnormal conditions comprising at least overcurrent, short circuit and slow or deep discharge. This detection is carried out without having to change an electronic component of the detection device, which is unique, or having to integrate a new electronic component based on the abnormal condition(s) that one wishes to detect. Another advantage is that it is not necessary for the detection device to comprise as many electronic circuits as there are abnormal conditions to be detected. This makes it possible to avoid an overload of the management system, which can lead to maintenance problems in the event of a breakdown (in particular in the search for the source of the breakdown).

[FIG. 4I] and [FIG. 4J] respectively illustrate the response of an analog integrator and a digital integrator to a V/2 discharge. The V/2 discharge, which takes place over a short period, for example about 15 s, makes it possible to determine the maximum current supported by the battery.

In certain embodiments, the battery management system (BMS) (1) for accumulators comprises at least around one comparator U1, a divider bridge (R1, R2, or R9, R4) mounted between the terminals of the modular assembly of the battery (4) or of a single cell of the battery (4) whose common point with the resistors is connected to the input of the negative terminal of the comparator U1 to supply a voltage whose value is proportional to the voltage V1, in the ratio defined by the values of the two resistors (R1, R2 or R9, R4), and the positive terminal of the comparator is connected to a diode or a supply cell (not shown) to define the reference voltage V2.

In certain embodiments, the integrator assembly comprises a resistor R5 connected between the common point of the divider bridge R1, R2 and the negative input of the comparator U1 and a resistor R8, capacitor C5 set, mounted in series by a common terminal, is connected by the other terminal of C5 to the output of the comparator U1 and the other terminal of R8 is connected to the common point of the two resistors R5, R8 and to the negative input of U1, the values R5 and C1 are adjusted to set the intervention time of the disconnection before the deterioration of the battery (4) in the event of overcurrent detection.

In certain embodiments, the comparator U1 has, at its output terminal, a voltage whose value characterizes a “non-conductive” state if the voltage applied to the input of the negative terminal of the amplifier U1 is greater than the value of the reference voltage V2 and a “conductive” state if the value of the voltage applied to the input of the negative terminal of the amplifier U1 is lower than the value of the reference voltage V2.

In certain embodiments, the detection device (2) comprises a capacitor C3 mounted in parallel with R2 that, combined with R1, forms a filter to filter out high-frequency disturbances.

In certain embodiments, mounted in parallel with R9 is a series assembly consisting of a resistor R3, a diode D3 with the cathode oriented toward the positive terminal and a Zener diode D4 with the cathode oriented toward the common point of the divider bridge R9, R4, a capacitor C5 connecting the common point of the bridge R9, R4 to the negative terminal of the battery (4) or of the cell or of the modular assembly of single elements. The pair (R3, C5) can be configured to obtain a fast time constant and the pair (R9, C5) can be configured to obtain a slow time constant.

In certain embodiments, a comparator circuit U2 with hysteresis, disposed downstream of the comparator circuit U1, comprises a hysteresis assembly around the amplifier U2 that receives, at the input of its negative terminal, the value of the voltage of the output of the amplifier U1.

In certain embodiments, the hysteresis comparator U2 comprises resistors R3, R4 mounted as a divider bridge between the positive and negative terminals of the battery (4) V1 and whose point common to R3 and R4 is connected to the positive input of the comparator U2 and a resistor R6 of which connects the output of U2 to its positive input to define the threshold and the hysteresis of the hysteresis comparator circuit comprising the amplifier U2.

In certain embodiments, the detection device (2) comprises a resistor R7 connected to the positive terminal of the battery (4), in series with a diode D1, in the forward direction in normal operation, and a capacitor C2 connected on the one hand to the cathode of the diode and on the other hand to the negative terminal of the battery (4) to allow it to be charged during normal operation; the supply inputs of the two comparators U1, U2 are connected to the point common to D1 and C2, this common point being used to maintain the supply of the amplifiers U1 and/or U2 when the battery (4) voltage collapses following a short circuit to allow the activation of the disconnection.

In certain embodiments, the reference voltage V2 at the positive input of the comparator U1 is supplied by a diode D2, which is a 16 V Zener. This diode is also connected by a resistor R1 to the common point to D1 and C2. The cathode of the diode D2 is also connected by a capacitor C1 to the negative terminal of the battery (4) or modular assembly of elements. The diode D2 can also be replaced by a voltage reference.

In certain embodiments, the hysteresis comparator U2 comprises a capacitor (C4, [FIG. 1] or C3, [FIG. 2] connected in parallel with a resistor (R4, [FIG. 1] or R3, [FIG. 2]) and which, combined with another resistor (R3, [FIG. 1] or R2, [FIG. 2]), forms a filter to filter out high-frequency disturbances and set a minimum tripping time.

In certain embodiments, the positive input of the hysteresis comparator U2, [FIG. 2] is connected by a resistor R2 to the point common to R3, R9 and R7.

In certain embodiments, the detection device (2) comprises a flip-flop connected to the output of U1 or U2 to store each action of the detection device (2) after each detection of deep discharges, overcurrent discharges and short-circuit discharges.

In certain embodiments, the battery management system (BMS) (1) communicates via the detection device (2) with a disconnection device (3) contained in the battery. The disconnection device is connected on the one hand to the negative pole of each modular block or each battery and on the other hand to the negative terminal of the battery (4), and uses at least two MOSFETs (M1, M2).

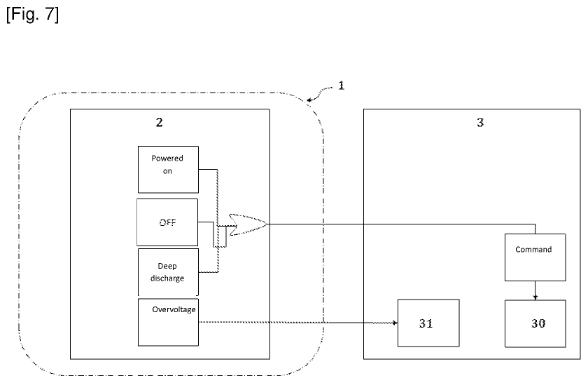

In another embodiment, the battery management system (BMS) (1) comprises, as illustrated in [FIG. 7], a disconnection device (3) that communicates with the detection device (2). The disconnection device is connected on the one hand to the negative pole of each modular block or each battery and on the other hand to the negative terminal of the battery (4), and uses at least two MOSFETs (M1, M2).

The disconnection device (3) comprises a switching device (30, 31) that can be either electromechanical, a relay for example, or semi-conductor.

Preferably, the disconnection device should have very low static consumption both in the on (conductive) state and in the off (non-conductive) state. For example and non-limitingly, a bistable relay or a MOSFET transistor meets this requirement.

In certain embodiments, the disconnection device (3) comprises a first switching device (30) in which

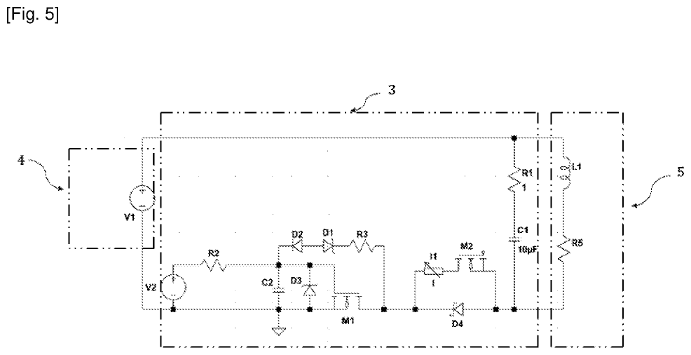

a first field-effect transistor (MOSFET) M1 connected by its source to the negative terminal of a set of single elements, this MOSFET M1 receives, on its gate, the voltage source that drives M1 (coming either from the output of the comparator U1 in the variant of [FIG. 2], or the output of the hysteresis comparator U2 in the variant of [FIG. 1]). This source delivers a chosen voltage (for example, 6 to 10 V) so that M1 is on;
a Zener diode D3 is connected in opposition between the gate and the source of M1, and a capacitor C2 to protect the gate of the MOSFET from excessively high or high-frequency voltages; and
a Zener diode D1 mounted in opposition between the gate of M1 and the drain and with a resistor R3 and a diode D2 in the forward direction in the drain-to-grid direction limit the switching speed of M1; and
a circuit consisting of a (conventional) diode or a Schottky diode D4 mounted in opposition on the drain of M1 and in series with a capacitor C1 and a resistor R1 connected to the positive terminal of the battery (4) to also limit the overvoltage when opening M1. In parallel on the diode or Schottky diode D4 a resistor is mounted, for example fixed or variable, I1, connected on the one hand to the cathode of the diode and on the other hand to the drain of a second MOSFET M2 whose source is connected to the anode of the diode or Schottky diode D4. The gate of M2 is controlled by an output of the analog or digital detection circuit to prevent or cut off the load or the charge current ([FIG. 7]). The resistor I1 makes it possible to limit the charge current.

[FIG. 5] illustrates the first switching member (30) and the switch to discharging.

In this embodiment, the battery (4) is in use by an external device (5), for example and non-limitingly a starter characterized by the pair L1-R5.

The diode D4 is conductive when the battery (4) is discharging. It must withstand the short-circuit current for at least 10 ms, and dissipate the Joule losses during a high-current discharge. In the case of a battery (4) formed by an “8S1P” assembly of 8 single cells in series, with an open-circuit voltage of 26.4 V and an internal resistance of 0.1 Ohm (with the connections), the short-circuit current can reach 264 A.

When opening the MOSFET M1, an overvoltage may occur greater than the drain-source voltage, Vds, of M1 due to the cancellation of the current in the inductor L1. D3 and C2, which then act as a filter to protect the gate of the MOSFET M1 from excessively high or high-frequency voltages and prevent it from being destroyed.

The Zener diode D1, with the resistor R3 and the diode D2, make it possible to limit the switching speed of M1 so that it does not oscillate. Switching (in voltage) is defined by the opening and closing of the MOSFET M1, in other words, its off state and its on state.

In certain embodiments, the disconnection device (3) comprises a second optocoupler switching device (31) in which

a first MOSFET M1 connected by its source to the negative terminal of a set of single elements, the gate of this MOSFET M1 is controlled by a voltage, this source delivering a voltage chosen so that M1 is always on,
a circuit consisting of a (conventional) diode or Schottky diode D4 mounted in opposition on the drain of M1, in parallel on the Schottky diode D4 a fixed resistor I1 is mounted connected on the one hand to the cathode of the Zener diode D4 and on the other hand to the drain of a second MOSFET M2 whose source is connected to the anode of the Schottky diode D4, the gate of M2 being connected to the positive terminal of said set of single elements,
a Zener diode D6 and a resistor R6 in series with the gate of M2, the Zener diode D6 being mounted in the forward direction in the drain-gate direction,
a Zener diode D5 mounted in opposition between the gate and the source of M2 to define, with the Zener diode D6, the value of the voltage at the gate of M2 and at which M2 is on,
a capacitor C5 connected between the gate and the source of M2 and in parallel with the Zener diode D5 to protect the gate of M2 from high-frequency voltages,
an optocoupler OP1 mounted between the gate and the source of M2 and in parallel with the capacitor C5 to block M2 in the event of the voltage or temperature of a cellular element or of the set of single cellular elements being exceeded, the MOSFET M2 then cutting off the charge current.

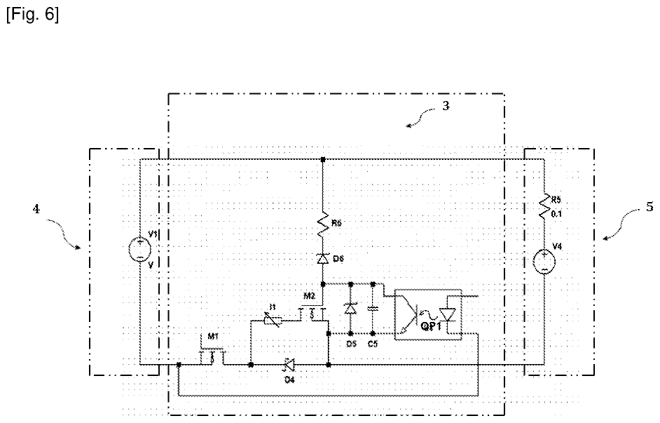

The appropriate value of the fixed resistor I1 can be obtained by replacing said resistor with a variable resistor and by dynamically modifying its value (for example and non-limitingly, by simulation).

[FIG. 6] illustrates the second switching device (30) and the load cut-off.

In this embodiment, the battery (4) is charged by means of an external device (5), for example and non-limitingly an alternator or a charger characterized by the pair V4-R5.

The external device provides, for example and non-limitingly, 28 V in normal operation, but can output a higher voltage in the event of a fault in its regulator. Standardized tests give a voltage of 1.5 times the nominal voltage of the battery, i.e. 42 V. In reality, it is possible for this voltage to reach 80 V.

The limitation of the charge current is provided by the diode D4 conducting in the discharge direction, and blocked in the charging direction, in parallel with a current limiting resistor.

Thus, the diode D4 must withstand the short-circuit current. This is feasible for a modular battery, but very difficult for a high-capacity battery. Indeed, a 17 Ah non-modular battery, for example, can supply a short-circuit current of more than 1800 A. Thus, the diode should be able to carry this current. Diodes that can carry this current do not exist as an “electronic component,” and in practice several lower-current components can be connected in parallel. However, balancing diode currents in parallel is almost impossible, because the forward voltage decreases sharply with temperature. Thus, the hottest diode carries all the current, which further increases its temperature until it is destroyed.

The MOSFET M1 is configured at its gate to be always on. The diode D4 is blocked on recharging, and the charge current passes through I1 and M2. I1 can also be a combination of resistors and polyswitches, or a semiconductor current regulator. M2 is on when its gate-source voltage V_{gs} is at 10 V, for example.

D6 is an 18 V Zener diode, for example, and D5 is a 10 V Zener diode. Thus, under a voltage of 28 V (alternator or charger voltage), D6 and D5 are at the limit of conduction, there is no current in R6 and V_{gs}=10 V. The voltage values of the diodes D5 and D6 therefore make it possible to define the value of the gate-source voltage of MOSFET M2. C5 protects the gate of MOSFET M2 from high-frequency voltages.

Detecting a fault in the charger comprises two measurements: the measurement of the voltage of each element, and the measurement of the overall voltage. If the voltage of an element exceeds 4 V or if the overall voltage exceeds 32 V, then the switching device (31) for switching to the load is actuated. Charging is again possible when the voltage has dropped below 26 V, for example, owing to a hysteresis comparator.

In the digital variant, the microprocessor will be wired with the battery to receive, on its inputs, both a voltage representative of the voltage of each cellular element V_{cec} constituting the battery and also the overall voltage measurement V_{global} of the battery, available on the conductors leading to the outer battery terminals. The program executable by the microprocessor will comprise a code module monitoring these two voltages V_{cec} and V_{global}; after comparing each one with a respective determined stored threshold, it triggers the cut-off by activating the disconnection element (31) when this threshold is exceeded.

If the voltage or temperature of a single element is exceeded, M2 is blocked by the optocoupler OP1. Indeed, the optocoupler OP1 comprises an LED (Light-Emitting Diode) and a transistor. Thus, if the voltage or temperature of a single element is exceeded, a current flows through the LED and causes the transistor to conduct. The gate-source voltage Vgs of the MOSFET M2 is returned close to 0 V (V_{cesat} for saturation collector-emitter voltage of OP1). M2 then cuts the charge current (D4 and M2 are blocked).

The current in the LED of OP1 is taken from the common point between M1 and the battery, therefore from the voltage of the battery (4), as shown in [FIG. 6], due to the disconnection between the 0 V of the battery and the 0 V of the alternator or charger.

Another alternative embodiment of the detection device is possible by using a low-pass RC circuit, non-linear components (diodes and Zener) and a comparator U1. An overvoltage detection assembly around the comparator U2.

It should be noted that this variant is also based on the voltage comparison by the use of a divider bridge R9, R4 and a comparator U1 that sends the disconnection signal directly to the disconnection assembly shown in [FIG. 3] and 4. The assembly also uses the same principle of supply by R7, D1, C2 of the comparators U1 and U2 to ensure detection even when the voltage of the battery (4) collapses following a short circuit.

The hysteresis mounting of U2 [FIG. 2] for R5, R6, C3 is identical to that of [FIG. 1] for R6, R4, C4. Only the resistor R2 [FIG. 2] is connected firstly to the common point of R5, C3 and the positive terminal of the comparator U2, and secondly to the common point of R9 and R3.

The positive input of the hysteresis comparator U2, [FIG. 2] is connected by a resistor R2 to the point common to R3, R9 and R7.

A Zener diode D2 is connected on the one hand to the positive input of the hysteresis comparator U2 and on the other hand by a resistor R1 to the point common to D1 and C2. The cathode of the diode D2 is also connected by a capacitor C1 to the negative terminal of the battery (4) or modular assembly of elements.

In parallel with R9, a series assembly is mounted consisting of a resistor R3, a diode D3 with the cathode oriented toward the positive terminal and a Zener diode D4 with the cathode oriented toward the common point of the divider bridge R9, R4. A capacitor C5 connects the common point of the bridge R9, R4 to the negative terminal of the battery (4) or of the cell or of the modular cell assembly.

In operation, as before, V1 represents the voltage of the battery (4). The reference voltage V2 at the positive input of the comparator U1 is supplied by a diode D2, which is a 16 V Zener. This diode is also connected by a resistor R1 to the common point to D1 and C2. The cathode of the diode D2 is also connected by a capacitor C1 to the negative terminal of the battery (4) or modular assembly of elements. Thus, the diode D2 is biased by R1 and filtered by C1. The voltage of the battery (4) is divided by R9-R4 so that when the voltage of the battery (4) slowly reaches (in discharge) the End Point Voltage (or EPV, which is 18 V for a 24 V battery and 9 V for a 12 V battery), the voltage at the negative input of U1 changes to 16 V, which causes the comparator U1 to switch from the “conductive” state to the “non-conductive” state (or from 1 to 0 in binary notation).

Below the end point voltage, or EPV, the time constancy of R9-C5 causes U1 to switch over with a typical delay of 1 s to 30 s. The delay is all the shorter as the voltage is far below the EPV. For very low voltages, which corresponds to a strong overcurrent or a short circuit, R3, D3 and D4 come in parallel with R9, which reduces the switching time of U1 to less than one second (0.1 s, typically). D4 is a 4.7 V Zener, for example.

Thus, on reading the characteristics described above, the BMS offers:

A single device that provides short-circuit, overcurrent and deep discharge protection at the same time;
Detection of an overcurrent for cut-off triggering by a voltage measurement;
A tripping current automatically adapted to the characteristics of the accumulator cells; no shunt, no magnetic sensor, no heating element Disconnection curve similar to a thermomagnetic curve, but with much better precision ([FIG. 9]);
The disconnection curve follows the aging of the accumulator elements;
Further adjustment is not necessary.

Other advantages also result from the management system as described in the present application, including, but are not limited to:

very low static consumption;
always-on circuits, no “on” and “sleep” mode;
a very high level of operational safety (high MTBF);
use of standard, non-strategic and non-use-specific components for BMS;
For analog embodiments: There is no software, no sequential logic, no clock, which avoids software problems and therefore battery deterioration in the event of a software problem;
No electromagnetic emission and better electromagnetic immunity (due to the use of low-power components).

The present application describes various technical characteristics and various advantages with reference to the figures and/or to the various embodiments. Those skilled in the art will understand that the technical features of a given embodiment may in fact be combined with features of another embodiment unless otherwise specified, or unless the combination does not provide a solution to at least one of the technical problems mentioned in this application. Additionally, the technical features described in a given embodiment may be isolated from the other technical features of that embodiment, unless otherwise specified.

It should be apparent to those skilled in the art that the present invention permits embodiments in many other specific forms without departing from the scope of the invention as claimed. Accordingly, the present embodiments should be considered illustrative, but may be modified within the scope defined by the protection sought, and the invention should not be limited to the details given above.

### Annex

This corresponds to a non-limiting example of a digital integrator program to implement the response of the integrator in [FIG. 4B]:

```
floatlastIntegratedValue = 0;
constfloat _SLOPE = −0.25;
constfloat _ORDINATE_ORIGIN = 2.5;
constfloat _COEF_PROGRESSIVENESS = 1;
constfloat _VALUE_REF_INTEGRATION = 10;
constfloat _RAPID_THRESHOLD=0.01;
constfloat _WEIGHTING=1;
loop( ){
  floatGeneralvoltage = IO_Voltage(1) * 7;// recovery of the battery
voltage that has been divided and rescaled
  lastIntegratedValue = Integration(generalvoltage, lastIntegratedValue);
  if (lastIntegratedValue>= 1 ) Disconnection ( );
}
floatIntegration (floatGeneralvoltage, floatlastValue){
  if(generalvoltage<= _VALUE_REF_INTEGRATION){
    if ((LastGeneralVoltage − generalVoltage)>_RAPID_THRESHOLD
    ||
  (LastGeneralVoltage − generalVoltage)< −_RAPID_THRESHOLD)
    _WEIGHT = 5;
    else
    _WEIGHT = 1;
  float x = (_SLOPE * generalvoltage +
  _ORDINATE_ORIGIN)*_WEIGHT;
  float y = integration(x, _COEF_PROGRESSIVENESS);
int value = lastValue + y;
return value;
  }
  return 0;
}
```

1. Method for detecting abnormal operating conditions of a single battery element or of a plurality of the set of single elements comprising the following steps:
sampling, at the common point of at least two resistors of a divider bridge with at least two resistors, at least one voltage proportional to the voltage at the terminals of the single element or of the set of single elements;
comparing the detected voltage with a reference threshold;
characterized in that said comparison with said reference threshold triggers the implementation of:
an evaluation of the evolution to come by an integral, evaluated analogically or digitally;
a comparison of this evaluation with a detection voltage threshold Td from which a disconnection of the single element or of the set of monitored single elements is carried out with respect, at least, to the terminals of the battery.

2. Method according to claim 1, characterized in that the step of evaluation by digital integral comprises:
steps for calculating the evolution slope (P) of the voltage curve by using at least two measurements taken;
at least one step of comparing the calculated slope with a stored “RapidThreshold” value, i.e., if the slope exceeds the “RapidThreshold” value, applying a weight coefficient increasing the acceleration of the evolution of the integral so that it crosses the trigger voltage threshold Td more quickly, or if it is not exceeded, a weight coefficient without acceleration effect.

3. Battery management system (BMS) (1) for accumulators, said batteries being capable of being constituted by a single element or several single elements that can be arranged in a modular assembly and connected in series, in parallel or in a plurality of series modular assemblies associated in parallel to form a battery (4), characterized in that said system comprises means suitable for performing the steps of a detection method according to one of the preceding claims.

4. Battery management system (BMS) (1) for accumulators according to claim 3, characterized in that it comprises at least:
a voltage divider bridge with at least two resistors (R1, R2 or R4, R9), for sampling at least one voltage proportional to the voltage at the terminals of the single element or of the set of single elements of the battery,
a detection device (2) for detecting abnormal conditions,
a disconnection device (3),
said detection device (2) communicating with the disconnection device (3) to activate it in the event of detection of abnormal conditions, said disconnection device being connectable to the battery (4) and comprising at least two MOSFETs.

5. Battery management system (BMS) (1) for accumulators according to claim 4, characterized in that it comprises a microprocessor equipped with at least one storage memory allowing the storage of at least one “Refintegration” threshold variable and a stored detection voltage value Td, the memory also containing the program executed by the microprocessor allowing the collection of the voltage curve points, the comparisons and decisions, the implementation of the equations allowing the integration, the microprocessor receiving as input the voltage V_{global} coming from the common point of the divider bridge between a resistor R1 and a resistor R2 and storing the measurements according to a determined frequency to observe the voltage curve V_{global}, and comparing the values of the voltage curve V_{global} with the “Refintegration” value, then when crossing of the “Refintegration” threshold is detected, said threshold being defined by the value stored in the memory, triggering the integration calculations of the curve V_{global} and comparing the values of the calculated integration curve (Vinteg) with a stored detection voltage value Td to activate the disconnection device effecting the cut-off.

6. Battery management system (BMS) (1) for accumulators according to claim 5, characterized in that the storage memory of the microprocessor also comprises the value of a “RapidThreshold” variable stored in order to determine, by comparing the variation dV of the voltage V_{global} between two successive instants t1 and t2 with the “RapidThreshold,” whether the calculation of the integral of the voltage curve V_{global} must take a weight coefficient into account or not.

7. Battery management system (BMS) (1) for accumulators according to claim 6, characterized in that the calculation of the integral comprises taking into account the “Slope and/or Ordinate” variables calculated by the microprocessor from the data of the recorded voltage curve V_{global}.

8. Battery management system (BMS) (1) for accumulators according to one of claim 3 or 4, characterized in that it comprises at least around one comparator U1, a divider bridge (R1, R2, or R9, R4) mounted between the terminals of the modular assembly of the battery (4) or of a single element of the battery (4) whose common point with the resistors is connected to the input of the negative terminal of the comparator U1 to supply a voltage whose value is proportional to the voltage value V1 at the terminals of the battery, in the ratio defined by the values of the two resistors (R1, R2 or R9, R4), and the positive terminal of the comparator is connected to a diode or a supply cell to define the reference voltage V2.

9. Battery management system (BMS) (1) for accumulators according to claim 8, characterized in that it comprises an integrator circuit around the comparator U1, the integrator circuit comprising:
a resistor R5 connected between the common point of the divider bridge R1, R2 and the negative input of the comparator U1, and a resistor R8, capacitor C1 set mounted in series by a common terminal, connected by the other terminal of C1 to the output of the comparator U1, the other terminal of R8 being connected to the common point of the two resistors R5, R8 and to the negative input of U1, the values R5 and C1 being adjusted to set the intervention time of the disconnection before the deterioration of the battery in the event of overcurrent detection.

10. Battery management system (BMS) (1) for accumulators according to claim 9, characterized in that a diode D2 is connected in parallel to resistor R5, with its cathode connected to the common point of the divider bridge to change the integration time constant of the integrator circuit in the event of an overcurrent or a short circuit.

11. Battery management system (BMS) (1) for accumulators according to one of claims 8 to 10, characterized in that the comparator U1 has, at its output terminal, a voltage whose value characterizes a “non-conductive” state if the voltage applied to the input of the negative terminal of the amplifier U1 is greater than the value of the reference voltage V2 and a “conductive” state if the value of the voltage applied to the input of the negative terminal of the amplifier U1 is lower than the value of the reference voltage V2.

12. Battery management system (BMS) (1) for accumulators according to claim 4, characterized in that the detection device (2) comprises a capacitor C3 mounted in parallel with R2 that, combined with R1, forms a filter to filter out high-frequency disturbances.

13. Battery management system (BMS) (1) for accumulators according to claim 8, characterized in that mounted in parallel with R9 are a series assembly consisting of a resistor R3, a diode D3 with the cathode oriented toward the positive terminal and a Zener diode D4 with the cathode oriented toward the common point of the divider bridge R9, R4, a capacitor C5 connecting the common point of the bridge R9, R4 to the negative terminal of the battery (4) or of the cell or of the modular assembly of single elements.

14. Battery management system (BMS) (1) for accumulators according to claims 8 to 13, characterized in that a comparator circuit U2 with hysteresis, disposed downstream of the comparator circuit U1, comprises a hysteresis assembly around the amplifier U2 that receives, at the input of its negative terminal, the value of the voltage of the output of the amplifier U1.

15. Battery management system (BMS) (1) for accumulators according to claim 14, characterized in that the hysteresis comparator U2 comprises resistors R3, R4 mounted as a divider bridge between the positive and negative terminals of the battery (4) V1 and whose point common to R3 and R4 is connected to the positive input of the comparator U2 and a resistor R6 of which connects the output of U2 to its positive input to define the threshold and the hysteresis of the hysteresis comparator circuit comprising the amplifier U2.

16. Battery management system (BMS) (1) for accumulators according to one of claims 8 to 15, characterized in that the detection device (2) comprises a resistor R7 connected to the positive terminal of the battery (4), in series with a diode D1, in the forward direction in normal operation, and a capacitor C2 connected on the one hand to the cathode of the diode and on the other hand to the negative terminal of the battery (4) to allow it to be charged during normal operation; the supply inputs of the two comparators U1, U2 are connected to the point common to D1 and C2, this common point being used to maintain the supply of the amplifiers U1 and/or U2 when the battery (4) voltage collapses following a short circuit to allow the activation of the disconnection.

17. Battery management system (BMS) (1) for accumulators according to one of claims 8 to 16, characterized in that the reference voltage V2 at the positive input of the comparator U1 is provided by a Zener diode D2, said Zener diode being connected by a resistor R1 to the point common to D1 and C2, the cathode of the Zener diode D2 also being connected by a capacitor C1 to the negative terminal of the battery (4) or modular set of elements.

18. Battery management system (BMS) (1) for accumulators according to one of claims 14 to 17, characterized in that the hysteresis comparator U2 comprises a capacitor (C4, C3) connected in parallel with a resistor (R4, R3) and which, combined with another resistor (R3, R2), forms a filter to filter out high-frequency disturbances and set a minimum tripping time.

19. Battery management system (BMS) (1) for accumulators according to one of claim 14 to 17 or 18, characterized in that the positive input of the hysteresis comparator U2 is connected by a resistor R2 to the common point to R3, R9 and R7.

20. Battery management system (BMS) (1) for accumulators according to one of claims 8 to 19, characterized in that the detection device (2) comprises a flip-flop connected to the output of U1 or U2 to store each action of the detection device (2) after each detection of deep discharges, overcurrent discharges and short-circuit discharges.

21. Battery management system (BMS) (1) for accumulators according to claim 4, characterized in that the disconnection device (3) comprises a switching device (30) in which
a first MOSFET M1 is connected by its source to the negative terminal of a set of single elements, said MOSFET M1 receiving, on its gate, the voltage source that drives M1, said source delivering a voltage chosen so that M1 is on, a Zener diode D3, connected in opposition between the gate and the source of M1, and a capacitor C2 protect the gate of the MOSFET from excessively high or high-frequency voltages, and
a Zener diode D1 mounted in opposition between the gate of M1 and the drain and with a resistor R3 and a diode D2 in the forward direction in the drain-to-grid direction limit the switching speed of M1, and
a circuit consisting of a Schottky diode D4 mounted in opposition on the drain of M1 and in series with a capacitor C1 and a resistor R1 connected to the positive terminal of the battery (4) to limit the overvoltage when opening M1, in parallel on the Schottky diode D4 a fixed resistor I1 is mounted connected on the one hand to the cathode of the diode and on the other hand to the drain of a second MOSFET M2 whose source is connected to the anode of the Schottky diode D4, the gate of M2 being controlled by an output of the detection circuit to prevent the load.

22. Battery management system (BMS) (1) for accumulators according to claim 4, characterized in that the disconnection device (3) comprises a second switching device (31) in which
a first MOSFET M1 connected by its source to the negative terminal of a set of single elements, the gate of this MOSFET M1 is controlled by a voltage, this source delivering a voltage chosen so that M1 is always on,
a circuit consisting of a Schottky diode D4 mounted in opposition on the drain of M1, in parallel on the Schottky diode D4 a fixed resistor I1 is mounted connected on the one hand to the cathode of the Schottky diode D4 and on the other hand to the drain of a second MOSFET M2 whose source is connected to the anode of the Schottky diode D4, the gate of M2 being connected to the positive terminal of said set of single elements,
a Zener diode D6 and a resistor R6 in series with the gate of M2, the Zener diode D6 being mounted in the forward direction in the drain-gate direction, a Zener diode D5 mounted in opposition between the gate and the source of M2 to define, with the Zener diode D6, the value of the voltage at the gate of M2 and at which M2 is on,
a capacitor C5 connected between the gate and the source of M2 and in parallel with the Zener diode D5 to protect the gate of M2 from high-frequency voltages, an optocoupler OP1 mounted between the gate and the source of M2 and in parallel with the capacitor C5 to block M2 in the event of the voltage or temperature of an element of the set of single elements being exceeded, the MOSFET M2 then cutting off the charge current.
